(19) United States
(12) Patent Application Publication
(10) Pub. No.: US 2010/0061135 A1
(43) Pub. Date: Mar. 11, 2010

(54) MAGNETIC WIRE UNIT AND STORAGE DEVICE

(75) Inventors: Keiichi Nagasaka, Isehara (JP); Hiroshi Ashida, Kawasaki (JP); Takao Ochiai, Kawasaki (JP); Ken Tamanoi, Kawasaki (JP)

Correspondence Address: GREER, BURNS & CRAIN, 300 S WACKER DR, 25TH FLOOR, CHICAGO, IL, 60606, US

(73) Assignee: FUJITSU LIMITED, Kawasaki-shi (JP)

(21) Appl. No.: 12/536,932

(22) Filed: Aug. 6, 2009

(30) Foreign Application Priority Data
Sep. 10, 2008 (JP) 2008-232730

(51) Int. Cl. G11C 19/00; G11C 11/14

(52) U.S. Cl. 365/80; 365/171

(57) ABSTRACT

A magnetic wire unit for storing information thereon includes a magnetic wire containing a material having an axis of easy magnetization, and extending in a first direction, the axis being switchable between the first direction and the second direction perpendicular to the first direction, the magnetic wire being capable of holding a plurality of magnetic domains representing information. The magnetic wire unit includes a current supply unit for applying an electric current to the magnetic wire so as to move magnetic domain walls defining the magnetic domains in the magnetic wire.

### CROSS-REFERENCE TO RELATED APPLICATION

This application is based upon and claims the benefit of priority of the prior Japanese Patent Application No. 2008-232730, filed on Sep. 10, 2008, the entire contents of which are incorporated herein by reference.

### FIELD

The embodiments discussed herein are related to a magnetic wire unit for storing information thereon, and a storage device having the magnetic wire unit.

### BACKGROUND

In recent years, the next generation of super-large nonvolatile memories has been studied and developed actively as alternatives to the current DRAMs (Dynamic Random Access Memory) or flash memories. The candidates may include an FeRAM (Ferroelectric Random Access Memory) applying a dielectric substance, a PRAM (Phase change RAM) applying the phase change of an insulator included in a memory, an MRAM (Magnetoresistive Random Access Memory) applying the TMR effect (tunnel magnetoresistance effect) and an RRAM (Resistive RAM) applying a giant resistance variation caused by the directions of application of the pulse current, the principle of which has not been clarified yet. However, all of these memory devices have advantages and disadvantages in performance and have not been developed to an extent as to be alternatives to the existing memories.

Recently, the technology called racetrack memory has been proposed which attempts to implement a mass storage (memory) by using the magnetic domain wall motion phenomenon with spin injection and the TMR effect. Examples of arts related to the racetrack are discussed in U.S. Pat. No. 6,834,005, Specification. Examples of arts related to the magnetic domain wall motion phenomenon are discussed in A. Yamaguchi et al., Phys, Rev, Lett., 92, 077205 (2004), for example. Other examples of arts related to the storage and memory applying the magnetic domain wall motion phenomenon with spin injection and the TMR effect are discussed in Japanese Laid-open Patent Publications No. 2007-324269, No. 2007-324172 and No. 2007-317895.

However, the development of the movement of the magnetic domain wall storage devices has several problems. It is preferable to reduce the current for driving magnetic domain walls of a magnetic wire (i.e. drive current for the magnetic domain walls).

For example, M. Hayashi et al., Phys, Rev, Lett., 97, 207205 (2006), S. S. R Parkin et al., Science 320, 190 (2008), and M. Hayashi et al., Science 320, 209 (2008) disclose the fact that the current value has reached 3×10¹² A/m² as a result of the evaluation on the current for driving magnetic domain walls with pulse voltage as fast as nanoseconds by using a conventionally used magnetic wire, which is a magnetic wire being an in-plane magnetic anisotropic film and containing an NiFe single layer as a material, and a high heat-releasing substrate. Also, as a result of the similar experiment performed by the inventor et al., the similar result has been obtained as those in M. Hayashi et al., Phys, Rev, Lett., 97, 207205 (2006), S. S. R Parkin et al., Science 320, 190 (2008), and M. Hayashi et al., Science 320, 209 (2008).

Accordingly, in order to obtain a magnetic domain wall motion storage device employing a magnetic wire and taking the heating by the wire itself and/or the vibration of a wire through which current is to be supplied to the wire, the value of the current for driving the magnetic domain walls is desirably reduced to at least one digit lower than the evaluation result.

On the other hand, it has been recently known that, in order to reduce the drive current, it is effective to use of a perpendicular magnetic film as the magnetic wire. However, when a perpendicular magnetic film is used as the magnetic wire, minute current moves the magnetic domain walls. Therefore, the magnetic domain walls may rest unstably, which means that information may be held unstably. Furthermore, the use of a perpendicular magnetization film as the magnetic wire requires the TMR element, which detects the movement of the magnetic domain walls of the magnetic wire, in a perpendicular magnetization structure, which may be difficult to produce.

### SUMMARY

According to an aspect of the invention, a magnetic wire unit for storing information thereon includes a magnetic wire containing a material having an axis of easy magnetization, and extending in a first direction, the axis being switchable between the first direction and the second direction perpendicular to the first direction, the magnetic wire being capable of holding a plurality of magnetic domains representing information; and a current supply unit for applying an electric current to the magnetic wire so as to move magnetic domain walls defining the magnetic domains in the magnetic wire.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 is a diagram schematically illustrating a part of a magnetic memory device according to a first embodiment;

FIG. 2 is a perspective diagram illustrating a recording area and a reserve area.

FIG. 3 is a section view of the magnetic memory device;

FIG. 4 is a diagram illustrating the temperature dependencies of the axis of easy magnetization of the corresponding magnetic materials;

FIG. 5 is a table illustrating the directions of the axis of easy magnetization and the ease of the movement of magnetic domain walls when the movement of magnetic domain walls is stopped and when the magnetic domain walls are moved according to the first embodiment;

FIG. 6 is a diagram schematically illustrating a part of the magnetic memory device according to a second embodiment;

FIG. 7 is a flowchart illustrating the control sequence by a control unit according to the second embodiment;

FIG. 8 is a table illustrating the directions of the axis of easy magnetization and the ease of the movement of magnetic domain walls when the movement of magnetic domain walls is stopped, when they are heated and when the magnetic domain walls are moved according to the second embodiment; and

FIG. 9 is a flowchart illustrating the control sequence by a control unit according to a variation example.

### DESCRIPTION OF EMBODIMENTS

### First Embodiment

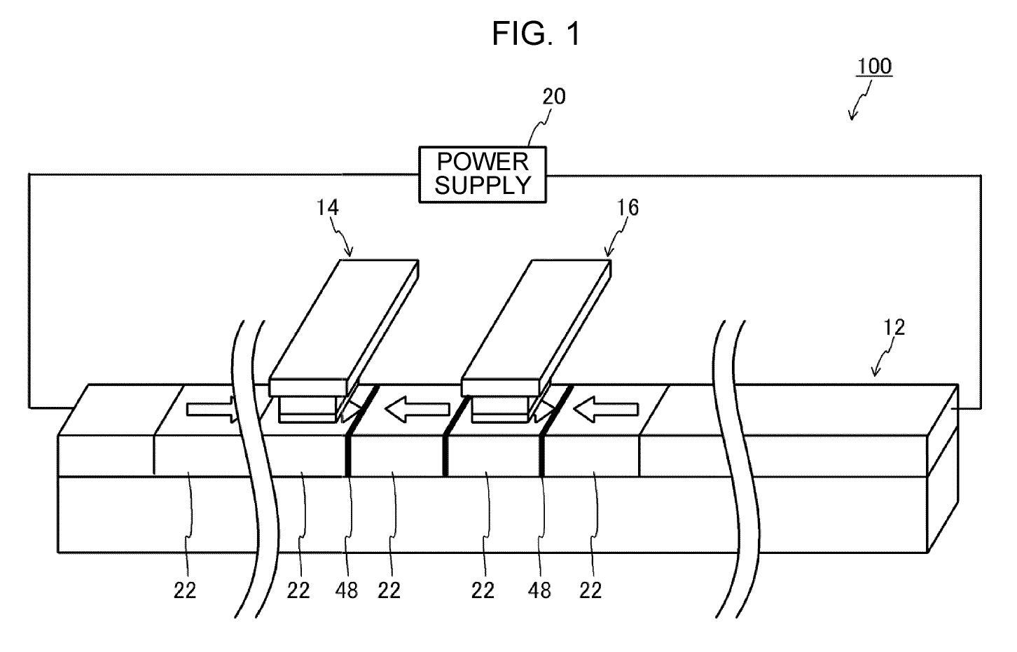

A magnetic memory device 100 being the storage device according to a first embodiment will be described with reference to FIG. 1 to FIG. 5 below.

FIG. 1 is a perspective diagram schematically illustrating a part of the magnetic memory device 100 according to the first embodiment. The magnetic memory device 100 includes, as illustrated in FIG. 1, a magnetic wire 12, a recording device 14, a reproducing device 16 and a power supply 20 being current supply unit for supplying current to the magnetic wire 12. Notably, the magnetic wire 12 and the power supply 20 are included to configure a magnetic wire unit.

The magnetic wire 12 has plural magnetic domains 22. Notably, forming physical slits on the magnetic domains 22 can increase the controllability over the positions of the magnetic domain walls. Depending on the direction of the magnetization (the direction of the arrow in FIG. 1) at each of the magnetic domains 22, the information “1” or “0” is recorded. Notably, the magnetic wire 12 has several hundreds to several tens of thousands of magnetic domains 22 in reality. On the magnetic wire 12, when the magnetization directions of the magnetic domains 22 adjacent to each other are opposite, a magnetic domain wall 48 exists between those magnetic domains 22. On the other hand, when the magnetization directions of the magnetic domains 22 adjacent to each other are the same, no magnetic domain walls 48 exist between those magnetic domains 22. Notably, the opposite magnetization directions across the magnetic domain wall 48 is a general characteristic of a ferromagnetic substance.

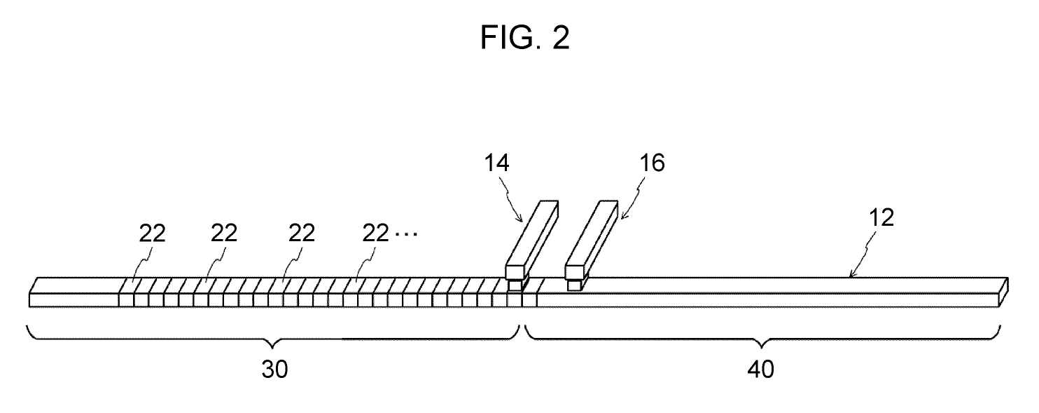

As illustrated in FIG. 2, the magnetic wire 12 is divided into a recording area 30 which is an area where information is to be recorded and a reserve area 40 which is the area excluding the recording area 30 in reality. Information is recorded within the magnetic domains 22 in the recording area 30. The specific material and others of the magnetic wire 12 will be described later.

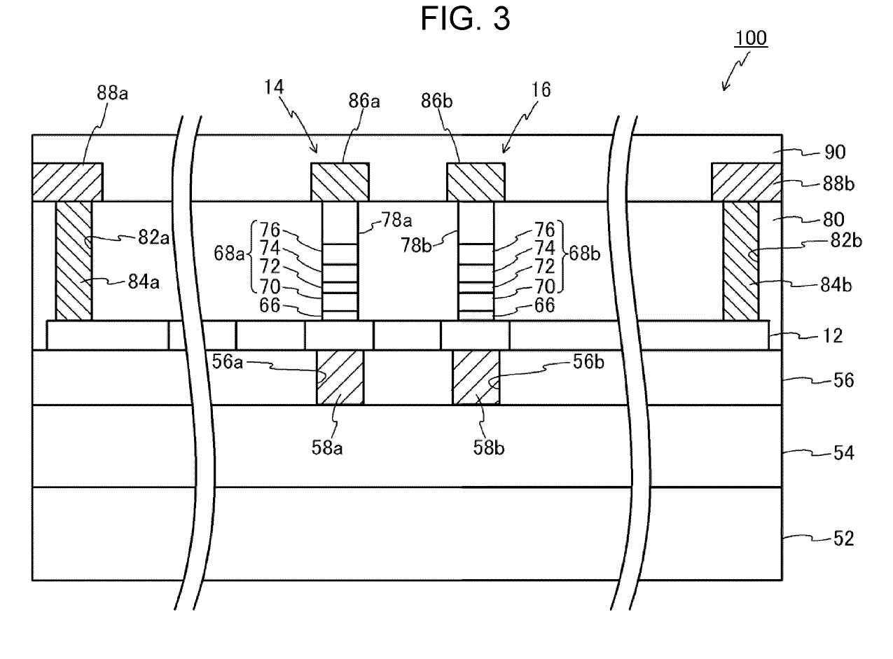

FIG. 3 illustrates a section view of the specific configuration of the magnetic memory device 100 in FIG. 1. As illustrated in FIG. 3, the magnetic wire 12 is provided above a silicon substrate 52, an inter-layer insulating layer 54 on the silicon substrate 52 and the upper sides of an inter-layer insulating layer 56 formed on the inter-layer insulating layer 54.

The silicon substrate 52 may have a transistor, for example, not illustrated, thereon as appropriately.

The inter-layer insulating layer 56 has channels 56a and 56b thereon. Within the channels 56a and 56b, a lower electrode 58a for of the recording device 14 and a lower electrode 58b of the reproducing device 16 are provided. The lower electrodes 58a and 58b are electrically connected to the transistors on the silicon substrate 52 appropriately.

At the positions facing the lower electrodes 58a and 58b through the magnetic wire 12, fixed magnetization layers 68a and 68b having a laminated ferromagnetic structure are provided through a barrier layer 66 containing MgO as a material are provided.

The fixed magnetization layers 68a and 68b are configured by a laminated film formed by sequentially laminating a ferromagnetic layer 70 containing CoFeB as a material, a nonmagnetic layer 72 containing Ru as a material, a ferromagnetic layer 74 containing CoFe as a material, and an antiferromagnetic layer 76 containing IrMn as a material. On the upper sides of the fixed magnetization layers 68a and 68b, connection electrodes 78a and 78b containing Ta as a material.

On the inter-layer insulating layer 56 having the magnetic wire 12, fixed magnetization layers 68a and 68b and connection electrodes 78a and 78b thereon, an inter-layer insulating layer 80 is provided with the top surface of the connection electrodes 78a and 78b exposed. The inter-layer insulating layer 80 has a pair of contact holes 82a and 82b across the magnetic wire 12. Within the contact holes 82a and 82b, contact plugs 84a and 84b are provided.

On the inter-layer insulating layer 80, an upper electrode 86a, an upper electrode 86b and wires 88a and 88b are provided. On the inter-layer insulating layer 80, an inter-layer insulating layer 90 containing the upper electrodes 86a and 86b and wires 88a and 88b is provided.

Notably, the lower electrode 58a, barrier layer 66, fixed magnetization layer 68a, connection electrode 78a and upper electrode 86a configure the recording device 14 for writing information to the magnetic domains 22 of the magnetic wire 12. The lower electrode 58b, barrier layer 66, fixed magnetization layer 68b, connection electrode 78b and upper electrode 86b configure the reproducing device 16 for reading information recorded on the magnetic domains 22 of the magnetic wire 12. Notably, in the recording device 14, the barrier layer 66 is formed appropriately. Considering the match between the forming processes of the recording device 14 and the reproducing device 16, forming the barrier layer 66 is preferable from the viewpoint of the ease of the manufacturing process. The recording device 16 may be a lead wire such as a word line for use in an MRAM instead of the one having the structure illustrated in FIG. 3, and the current magnetic field by the current applied to the lead wire may be applied thereto. The reproducing device 16 may apply current between the upper and lower terminals (86b and 58b) of the TMR with the terminal 58b below the magnetic wire 12. Alternatively, for example, without the lower terminal 58b, the reproducing device 16 may apply current between the upper terminal 86b and the terminal 88b for applying the current for driving magnetic domain walls.

The wires 88a and 88b are electrically connected to one end and the other end of the magnetic wire 12 through the contact plugs 84a and 84b. The wires 88a and 88b are electrically connected to the power supply 20 illustrated in FIG. 1.

In the magnetic memory device 100 configured as described above, the magnetic domain walls 48 can be moved appropriately by the spin torque caused when current (pulse current) is fed in the longitudinal direction of the magnetic wire 12. With that, the information written on the magnetic domains 22 can be shifted appropriately. In other words, for example, when current is fed to the left in FIG. 2, the electron spin flows to the right. Thus, the magnetic domain walls 48 move to the right-hand side. When current is fed to the right in FIG. 2, the electron spin flows to the left. Thus, the magnetic domain walls 48 move to the left-hand side.

Therefore, in order to write (record) or read (reproduce) information in the magnetic memory device 100, the movement above moves the magnetic domains 22 from the recording area 30 to the reserve area 40 illustrated in FIG. 2, whereby the magnetic domains 22 on which the recording (or reproduction) are to be performed are moved to the position facing the recording device 14 (or the reproducing device 16).

Then, information is written (or recorded) onto the magnetic domains 22 of the magnetic wire 12 by defining the magnetization direction of the magnetic domains 22 of the magnetic wire 12 to the same direction as (or in parallel with) the magnetization direction of the fixed magnetization layer 68a or in the opposite direction to (or in anti-parallel with) the magnetization direction of the fixed magnetization layer 68a.

More specifically, in order to invert the magnetization direction of the magnetic domains 22 of the magnetic wire 12 from the anti-parallel state to the parallel state, the potential of the lower electrode 58a is defined higher than the potential of the upper electrode 86a. Thus, current flows from the magnetic wire 12 side to the fixed magnetization layer 68a side in the direction perpendicular to the film surface, and the spin polarized conduction electrons flow from the fixed magnetization layer 68a into the magnetic wire 12, causing the exchange interaction with the electrons in the magnetic wire 12. As a result, torque occurs between the electrons, and, when the torque is large enough, the magnetization direction of the magnetic domains 22 of the magnetic wire 12 is inverted from the anti-parallel state to the parallel state.

On the other hand, in order to invert the magnetization direction of the magnetic domains 22 of the magnetic wire 12 from the parallel state to the anti-parallel state, the potential of the upper electrode 86a is defined higher than the potential of the lower electrode 58a. Thus, the opposite effect to the one described above inverts the magnetization direction of the magnetic domains 22 of the magnetic wire 12 from the parallel state to the anti-parallel state.

On the other hand, the information written (or recorded) on the magnetic domains 22 of the magnetic wire 12 is read (or reproduced) by detecting the value of resistance between the upper electrode 86b and the lower electrode 58b included in the reproducing device 16. More specifically, when the magnetization direction of the fixed magnetization layer 68b and the magnetization direction of the magnetic domains 22 facing the fixed magnetization layer 68b are opposite (or anti-parallel), a high-resistance state is obtained between the lower electrode 58b and the upper electrode 86b. On the other hand, when the magnetization direction of the fixed magnetization layer 68b and the magnetization direction of the magnetic domains 22 facing the fixed magnetization layer 68b are the same (or parallel), a low-resistance state is obtained between the lower electrode 58b and the upper electrode 86b. Thus, because the high-resistance state and the low-resistance state exist, associating those two states with data “1” and “0” allows the identification of the information written in the magnetic domains 22 of the magnetic wire 12 as either “1” or “0”.

Next, the materials of the magnetic wire 12 will be described.

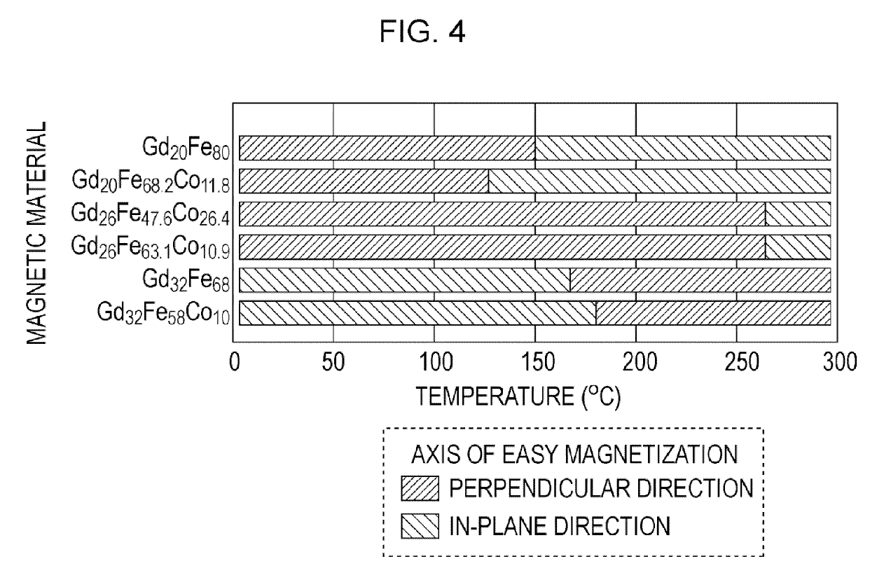

According to the first embodiment, an alloy containing Gd and Fe is adopted as a material of the magnetic wire 12. More specifically, Gd₃₂Fe₆₈ or Gd₃₂Fe₅₈Co₁₀ illustrated in FIG. 4 is adopted (where the numerical subscript of each of the materials refers to the atomic percent (atm %)). As illustrated in FIG. 4, these materials Gd₃₂Fe₆₈ and Gd₃₂Fe₅₈Co₁₀ exhibit a first state that the axis of easy magnetization is in the in-plane direction when the temperature is lower than approximately 170° C. to 180° C. Those materials exhibit a second state that the axis of easy magnetization is in the perpendicular direction when the temperature is higher than approximately 170° C. to 180° C. In other words, those materials have the state transition from the first state to the second state with the increase in temperature and, conversely, have the state transition from the second state to the first state with the decrease in temperature. The temperature that the state transition as described above occurs is called “transition temperature”. Notably, the relationship between the composition of the magnetic material and the temperature dependency of the axis of easy magnetization illustrated in FIG. 4 is determined from the direction of the axis of easy magnetization based on the magnetization curve (M-H curve) in the in-plane and perpendicular direction by using, as the evaluation sample, the sample having GdFe(Co) 40 nm thick being protected vertically between a nonmagnetic material SiN.

Next, the effects by the use of the material will be described in stopping the movement of the magnetic domain walls 48 and in moving the magnetic domain walls 48.

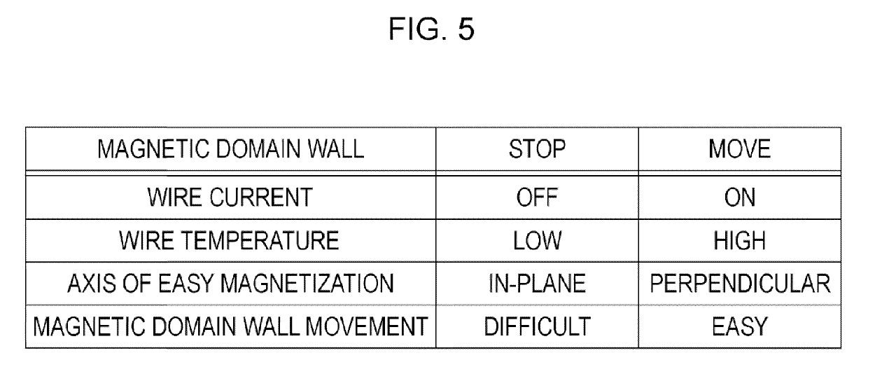

As illustrated in FIG. 5, in order to stop the movement of the magnetic domain walls 48, the current supply is turned off from the power supply 20 to the magnetic wire 12. Thus, the temperature of the magnetic wire 12 can be kept lower (than the transition temperature). Hence, the axis of easy magnetization is turns to the in-plane direction. Therefore, in order to stop the movement of magnetic domain walls, the axis of easy magnetization is defined in the in-plane direction with which the magnetic domain walls 48 is difficult to move. As a result, the positions of the magnetic domain walls 48 (that is, the information recorded on the magnetic domains 22) can be held in a stable manner.

On the other hand, in order to move the magnetic domain walls 48, the current supply is turned on from the power supply 20 to the magnetic wire 12. Thus, the joule heat caused by the current increases the temperature of the magnetic wire 12 (more than the transition temperature). Hence, the axis of easy magnetization makes a transition to the perpendicular direction. Therefore, in order to move the magnetic domain walls 48, the axis of easy magnetization is defined to the perpendicular direction with which the magnetic domain walls 48 is easy to move. As a result, the magnetic domain walls 48 can be moved easily, that is, the current for moving the magnetic domain walls 48 can be reduced.

Notably, in the design stage, the magnetic wire 12 is desirably designed in consideration of the specific resistance and/or current density of the magnetic wire 12 such that the temperature of the magnetic wire 12 can be higher than the transition temperature when the current (which is the current for driving the magnetic domain walls) is supplied for the movement of the magnetic domain walls 48.

As described in detail above, according to the first embodiment, at the first state where the axis of easy magnetization of the magnetic wire 12 is in the in-plane direction, the current supply for moving the magnetic domain walls 48 is not performed. Only at the second state where the axis of easy magnetization is in the perpendicular direction with which the current for moving the magnetic domain walls 48 is small, the current supply for moving the magnetic domain walls 48 is performed. Performing the sequence allows the reduction of the current to be supplied for the movement of the magnetic domain walls. Furthermore, because it is easy to move the magnetic domain walls, the speed of the response of the movement of the magnetic domain walls to the current application to the magnetic wire 12 can be increased. In addition, because, when the magnetic domain walls 48 are not moved, the axis of easy magnetization is in the in-plane direction, the magnetic domain walls can rest stably, which means that information can be held stably.

According to the first embodiment, because the sequence can be performed without performing any special control, the current to be supplied for moving the magnetic domain walls can be reduced easily.

Notably, having described, according to the first embodiment the case that the direction of the axis of easy magnetization is changed by using the increase in temperature of the magnetic wire 12 due to the joule heat caused by the current when the magnetic domain walls 48 are moved, the present invention is not limited thereto. For example, a different mechanism for adjusting the temperature of the magnetic wire 12 may be provided near the magnetic wire 12 so as to adjust the temperature of the magnetic wire 12. The example adopting such a mechanism is a second embodiment which will be described next.

### Second Embodiment

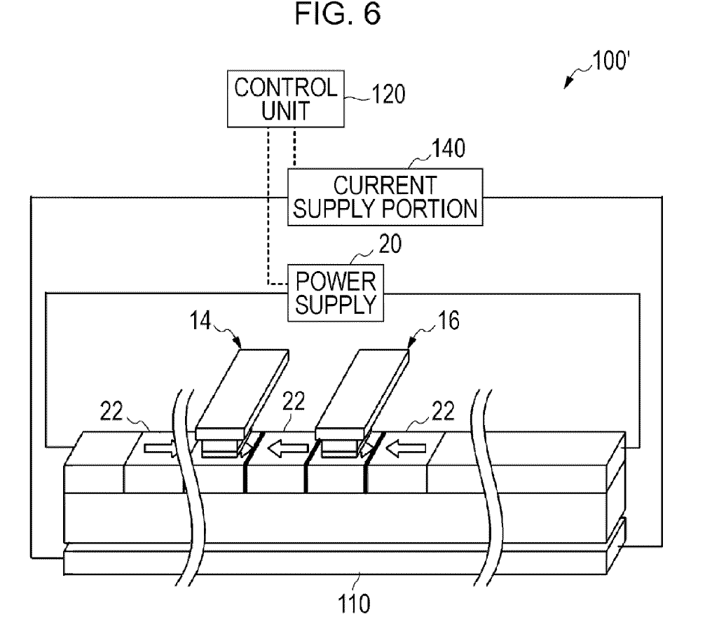

With reference to FIG. 6 to FIG. 8, the second embodiment will be described below. The second embodiment is characterized in that a heater is used to actively perform the temperature control over the magnetic wire 12, which has been described according to the first embodiment.

FIG. 6 schematically illustrates a part of a magnetic memory device 100′ according to the second embodiment. As illustrated in FIG. 6, the magnetic memory device 100′ includes, in addition to the configuration (refer to FIG. 1 to FIG. 3) according to the first embodiment, a heater 110 provided near the magnetic wire 12, a current supply portion 140 that supplies current to the heater 110, and a control unit 120 that controls the operations by the current supply portion 140 and the power supply 20.

The heater 10 may contain a material having a larger specific resistance than those of a heating wire and/or the magnetic wire 12, for example, and generates heat with the current supplied from the current supply portion 140 under the control of the control unit 120. Notably, according to this embodiment, the heater 110, control unit 120 and current supply portion 140 are included to configure transition means.

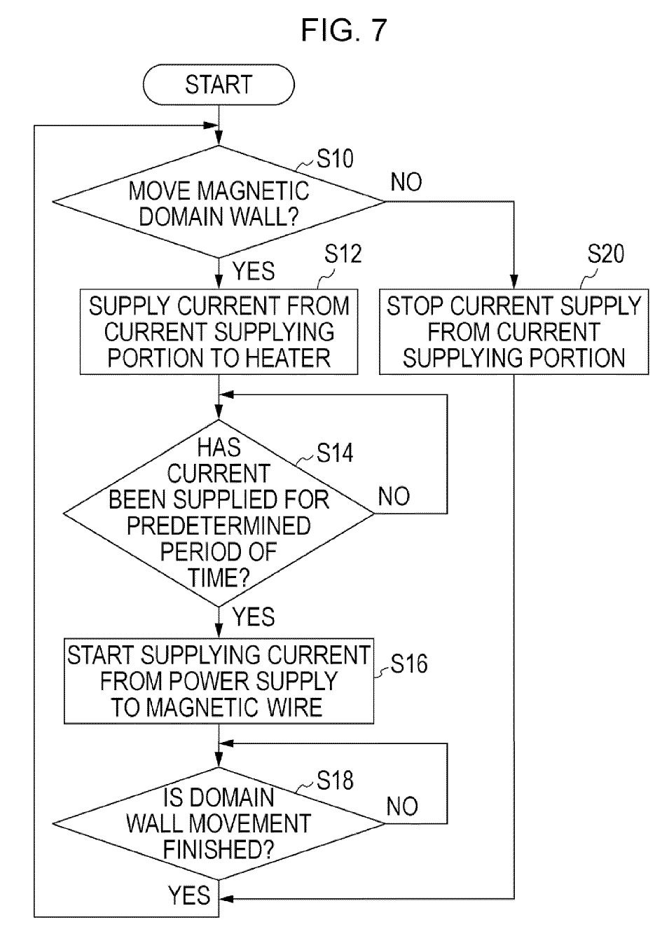

Next, the processing by the control unit 120 will be described by following the flowchart in FIG. 7.

The control unit 120 in step S10 in FIG. 7 determines whether the magnetic domain walls 48 are to be moved or not. In this case, the determination of this step results in YES if, for example, a command for recording information (data) or a command for reproducing information (data) on the magnetic wire 12 is issued by an external host.

If the determination here results in YES, the control unit 120 in the next step S12 instructs the current supply portion 140 to perform the current supply to the heater 110.

Next, the control unit 120 in step S14 waits until current is supplied from the current supply portion 140 to the heater 110 for a predetermined period of time. The waiting for a predetermined period of time in step S14 increases the temperature of the magnetic wire 12 over the transition temperature by receiving the heat by the heater 110.

Next, the control unit 120 in step S16 starts the current supply from the power supply 20 to the magnetic wire 12 and starts moving the magnetic domain walls 48. Then, when the control unit 120 in step S18 determines that the movement of the magnetic domain walls 48 is finished, the control unit 120 returns to step S10.

On the other hand, if in step S10 the determination results in NO, that is, it is determined that the movement of the magnetic domain walls is not to be performed, the current supply from the current supply portion is stopped (or the current supply stop state is kept if the current supply has been already stopped) in step S20.

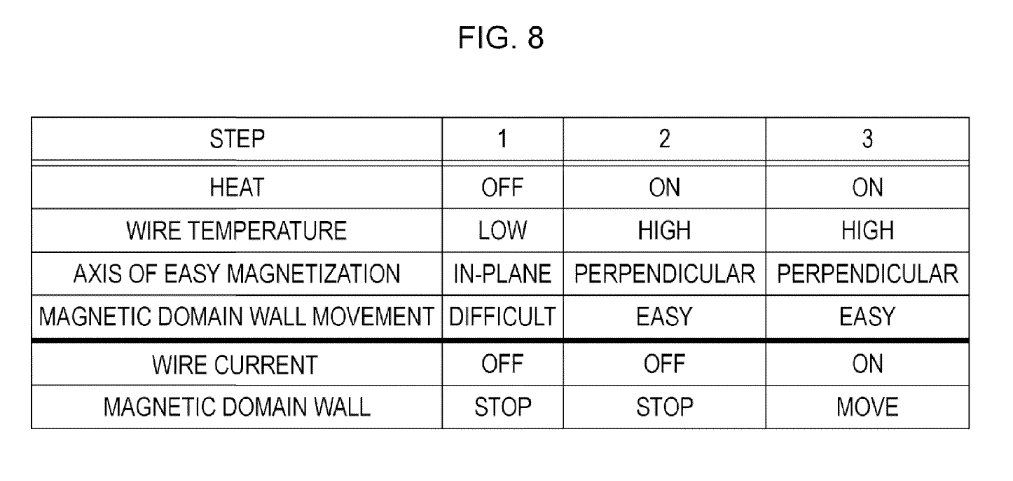

By performing the processing in FIG. 7, the temperature of the magnetic wire 12 can be kept lower (than the transition temperature) as illustrated in step 1 in FIG. 8 because the heater 110 does not generate heat (or is turned off) when the movement of magnetic domain walls is not to be performed. Therefore, the axis of easy magnetization turns to the in-plane direction. In this way, defining the axis of easy magnetization to the in-plane direction with which the movement of the magnetic domain walls 48 is difficult allows the positions of the magnetic domain walls 48 (that is the information recorded in the magnetic domains 22) to be held in a stable manner.

On the other hand, the temperature of the magnetic wire 12 becomes higher (than the transition temperature) because the heater 110 generates heat as illustrated in step 2 in FIG. 8 in the stage before the magnetic domain walls 48 are moved. Therefore, the axis of easy magnetization is defined to the direction (which is the perpendicular direction) with which the movement of the magnetic domain walls 48 is easy.

Furthermore, because, in order to move the magnetic domain walls 48, the current is supplied to the magnetic wire 12 by keeping the state in step 2 as illustrated in step 3 in FIG. 8, the magnetic domain walls 48 can be moved easily, that is, the current for moving the magnetic domain walls 48 can be reduced.

As described above in detail, according to the second embodiment, like the first embodiment, at the first state that the axis of easy magnetization of the magnetic wire 12 is in the in-plane direction, the current supply is not performed for moving the magnetic domain walls 48. At the second state that the axis of easy magnetization is in the direction (which is the perpendicular direction) with which the current for moving the magnetic domain walls 48 is small, the current supply is performed for moving the magnetic domain walls 48. Therefore, the current to be supplied for the movement of magnetic domain walls can be reduced. Furthermore, because the movement of magnetic domain walls can be performed easily, the speed of the response of the movement of magnetic domain walls to the current application to the magnetic wire 12 can be increased. Still further, in order to stop the movement of magnetic domain walls, the axis of easy magnetization is defined to the direction (which is the in-plane direction) with which the magnetic domain walls 48 are difficult to move. Therefore, the positions of the magnetic domain walls 48 (that is, the information recorded in the magnetic domains 22) can be held in a stable manner. Notably, the second embodiment is particularly effective when only the current supply to the magnetic wire 12 does not cause the temperature of the magnetic wire 12 over the transition temperature, as in described according to the first embodiment.

Having described, according the embodiments, the case where two kinds of materials Gd₃₂Fe₆₈ and Gd₃₂Fe₅₈Co₁₀ are used among the materials illustrated in FIG. 4, the present invention is not limited thereto. The other materials (Gd₂₀Fe₈₀, Gd₂₀Fe_{68.2}Co_{11.8}, Gd₂₆Fe_{47.6}Co_{26.4} and Gd₂₆Fe_{63.1}Co_{10.98}) illustrated in FIG. 4 may be adopted. In this case, as illustrated in FIG. 4, unlike Gd₃₂Fe₆₈ or Gd₃₂Fe₅₈Co₁₀ used according to the embodiments, when the temperature is lower than the transition temperature, the axis of easy magnetization turns to the perpendicular direction. When it is higher than the transition temperature, the axis of easy magnetization is in the in-plane direction.

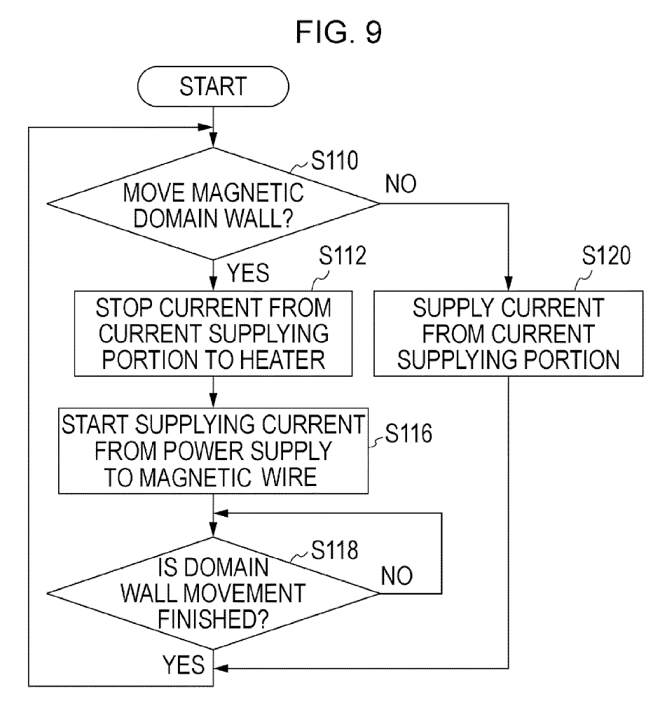

Therefore, preferably in this case, the same configuration as that of the second embodiment (refer to FIG. 6) is used, and then the sequence as illustrated in FIG. 9 is adopted.

In FIG. 9, if it is determined in step S110 that the magnetic domain walls 48 are not to be moved (or if the determination in step S110 results in NO), current is supplied from the current supply portion 140 to the heater 110 in step S120. If it is determined in step S110 that the magnetic domain walls 48 are to be moved (or if the determination in step S110 results in YES), the current supply from the current supply portion 140 is stopped. Notably, the processing in steps S116 and S118 is the same as that in steps S16 and S18 in FIG. 7.

Performing the processing provides the same effects as those of the second embodiment even when a material (such as Gd₂₀Fe₈₀, Gd₂₀Fe_{68.2}Co_{11.8}, Gd₂₆Fe_{47.6}Co_{26.4}, and Gd₂₆Fe_{63.1}Co_{10.98}) is used which has the axis of easy magnetization in the perpendicular direction when the temperature is lower than the transition temperature and has the axis of easy magnetization in the in-plane direction when the temperature is higher than the transition temperature.

Notably, according to this variation example, the current for the movement of magnetic domain walls is supplied to the magnetic wire 12 at the state that the current supply to the heater 110 is stopped. The current supplied to the magnetic wire 12 increases the temperature of the magnetic wire 12, and the temperature of the magnetic wire 12 may possibly exceed the transition temperature. Therefore, assuming such a case, a cooling mechanism (such as a mechanism including a Peltier device) may be provided near the magnetic wire 12. In supplying current to the magnetic wire 12, the cooling mechanism may be used to cool the magnetic wire 12.

Having described, according to the embodiments and variation example, that the GdFe(Co)-based material is used as the material of the magnetic wire 12, the present invention is not limited thereto. For example, a rare earth material similar to GdFe, such as TbFe, may also be used to obtain the same effects as those of the embodiments. Without limiting to the material, any magnetic material may be adopted which can cause a transition of the axis of easy magnetization according to various conditions.

Having described, according to the embodiments, the temperature of the magnetic wire 12 is changed in order to cause a transition of the direction of the axis of easy magnetization, the invention is not limited thereto. For example, by controlling the pressure on the magnetic wire 12, a transition of the direction of the axis of easy magnetization may be caused.

Having described, according to the embodiments, the case where the magnetic wire unit at least including a magnetic wire and a power supply is adopted to the magnetic memory device as illustrating in FIG. 1 and FIG. 6, the invention is not limited thereto. It is also applicable to various apparatus (such as a racetrack storage apparatus and an MRAM) in addition.

The magnetic wire unit disclosed herein has advantages that the current for the movement of the magnetic domain walls can be reduced and that information can be held in a stable manner. The storage device disclosed herein has an advantage that the current consumption in recording or reproducing can be reduced.

The embodiments described above are the preferred examples embodying the present invention. However, the invention is not limited thereto, but various changes and modifications may be made without departing from the spirit and scope of the present invention.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present inventions have been described in detail, it should be understood that the various changes, substitutions, and alterations could be made hereto without departing from the spirit and scope of the invention.

What is claimed is:

1. A magnetic wire unit for storing information thereon comprising:
a magnetic wire containing a material having an axis of easy magnetization, and extending in a first direction, the axis being switchable between the first direction and the second direction perpendicular to the first direction, the magnetic wire being capable of holding a plurality of magnetic domains representing information; and
a current supply unit for applying an electric current to the magnetic wire so as to move magnetic domain walls defining the magnetic domains in the magnetic wire.

2. The magnetic wire unit according to claim 1, wherein the temperature of the magnetic wire is changed by the joule heat caused by the electric current applied so that the axis is switched between the first direction and the second direction.

3. The magnetic wire unit according to claim 1, further comprising:
a transition unit for controlling the direction of the axis.

4. The magnetic wire unit according to claim 1, wherein the transition unit controls the temperature of the magnetic wire so that the axis is switched between the first direction and the second direction.

5. The magnetic wire unit according to claim 1, wherein the transition unit controls the pressure applied on the magnetic wire so that the axis is switched between the first direction and the second direction.

6. The magnetic wire unit according to claim 3, wherein the transition unit controls the direction of the axis so that the axis is in the first direction when the current supply applies no current to the magnetic wire, and the axis is in the second direction when the current supply applies current to the magnetic wire.

7. The magnetic wire unit according to claim 1, wherein the magnetic wire consists of an alloy containing Gd and Fe.

8. A storage device comprising:
a magnetic wire unit for storing information thereon including:
a magnetic wire containing a material having an axis of easy magnetization, and extending in a first direction, the axis being switchable between the first direction and the second direction perpendicular to the first direction, the magnetic wire being capable of holding a plurality of magnetic domains representing information, and
a current supply unit for applying an electric current to the magnetic wire so as to move magnetic domain walls defining the magnetic domains in the magnetic wire;
a recording unit adjacent to the magnetic wire, for switching the direction of the magnetic domains so as to writing information to the magnetic wire; and
a reproducing unit adjacent to the magnetic wire, for reading the information recorded on the magnetic wire.
